(19) United States
(12) Patent Application Publication
(10) Pub. No.: US 2012/0286371 A1
(43) Pub. Date: Nov. 15, 2012

(54) Field Effect Transistor Device With Self-Aligned Junction

(75) Inventors: Dechao Guo, Wappingers Falls, NY (US); Pranita Kulkarni, Slingerlands, NY (US); Ramachandran Muralidhar, Mahopac, NY (US); Chun-Chen Yeh, Clifton Park, NY (US)

(73) Assignee: INTERNATIONAL BUSINESS MACHINES CORPORATION, Armonk, NY (US)

(21) Appl. No.: 13/558,664

(22) Filed: Jul. 26, 2012

Related U.S. Application Data
(62) Division of application No. 12/857,013, filed on Aug. 16, 2010.

(51) Int. Cl. H01L 29/78

(52) U.S. Cl. 257/408; 257/E29.255

(57) ABSTRACT

A field effect transistor device includes a substrate including a source region, a drain region, and a channel region disposed between the source region and the drain region, wherein the source region is connected to the channel region with a source extension portion, and the drain region is connected to the channel region with a drain extension portion, wherein the channel region includes a source transition portion including n-type and p-type ions and a drain transition portion including n-type and p-type ions, and a gate stack portion disposed on the channel region.

### CROSS-REFERENCE TO RELATED APPLICATIONS

This is a divisional application of application Ser. No. 12/857,013, filed Aug. 16, 2010, which is incorporated by reference herein.

### FIELD OF INVENTION

The present invention relates to semiconductor field effect transistors.

### DESCRIPTION OF RELATED ART

Planar field effect transistor (FET) devices include a gate stack disposed on a channel region of a substrate and source and drain regions disposed adjacent to the channel region. The source and drain regions may be electrically connected to other devices via conductive contacts.

A number of planar FETs may be grouped on a substrate; the distance between the gates of the FETs or pitch, becomes smaller as the scale of the FETs are reduced. The reduction in pitch affects the gate length and electrostatic properties of the devices. The reduction in pitch results in source and drain contacts becoming closer, which may increase the parasitic capacitance of the FETs.

The source and drain regions include ion doped material adjacent to the channel region. The interfaces (junctions) between the source and drain regions and the channel region may be formed relative to the gate to affect the electrostatic properties of the device. An overlapped device includes a junction under the gate stack, while an underlapped device includes a junction disposed outside the edges of the gate stack. The amount of overlap in a device affects the parasitic capacitance in the device.

### BRIEF SUMMARY

In one aspect of the present invention, a method for fabricating a field effect transistor device includes forming a dummy gate stack on a first portion of a substrate, forming a source region and a drain region adjacent to the dummy gate stack, forming a ion doped source extension portion in the substrate, the source extension portion extending from the source region into the first portion of the substrate, forming an ion doped drain extension portion in the substrate, the drain extension portion extending from the drain region into the first portion of the substrate, removing a portion of the dummy gate stack to expose an interfacial layer of the dummy gate stack, implanting ions in the source extension portion and the drain extension portion to form a channel region in the first portion of the substrate, removing the interfacial layer, and forming a gate stack on the channel region of the substrate.

In another aspect of the present invention, a method for fabricating a field effect transistor device includes forming a dummy gate stack on a first portion of a substrate, forming a source region and a drain region adjacent to the dummy gate stack, forming a ion doped source extension portion in the substrate, the source extension portion extending from the source region into the first portion of the substrate, forming an ion doped drain extension portion in the substrate, the drain extension portion extending from the drain region into the first portion of the substrate, removing the dummy gate stack to expose the first portion of the substrate, removing the exposed first portion of the substrate including portions of the source extension portion and the drain extension portion to form a cavity in the substrate, epitaxially forming a channel region in the cavity, forming a gate stack on the channel region of the substrate.

In yet another aspect of the present invention, a field effect transistor device includes a substrate including a source region, a drain region, and a channel region disposed between the source region and the drain region, wherein the source region is connected to the channel region with a source extension portion, and the drain region is connected to the channel region with a drain extension portion, wherein the channel region includes a source transition portion including n-type and p-type ions and a drain transition portion including n-type and p-type ions, and a gate stack portion disposed on the channel region.

In yet another aspect of the present invention, a field effect transistor device includes a substrate including a source region, a drain region, and a cavity disposed between the source region and the drain region, a channel region including a doped silicon material disposed in the cavity, wherein the source region is connected to the channel region with a source extension portion, and the drain region is connected to the channel region with a drain extension portion, and a gate stack portion disposed on the channel region.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a side cut-away view of an exemplary embodiment of a field effect transistor (FET) device.

FIGS. 2-6 illustrate a side cut-away view of an exemplary method for fabricating the device of FIG. 1, in which:

FIG. 2 illustrates a substrate and a dummy gate stack;

FIG. 3 illustrates a resultant structure following the removal of a polysilicon material from the dummy gate stack;

FIG. 4 illustrates the implantation of ions;

FIG. 5 illustrates the removal of portions of an interfacial layer; and

FIG. 6 illustrates the formation of a gate stack.

FIGS. 7-11 illustrate an alternate exemplary method for forming an alternate embodiment of a FET device, in which:

FIG. 7 illustrates a substrate and a dummy gate stack;

FIG. 8 illustrates the removal of the dummy gate stack;

FIG. 9 illustrates the removal of portions of the substrate;

FIG. 10 illustrates the formation of a channel region; and

FIG. 11 illustrates the formation of a gate stack.

### DETAILED DESCRIPTION

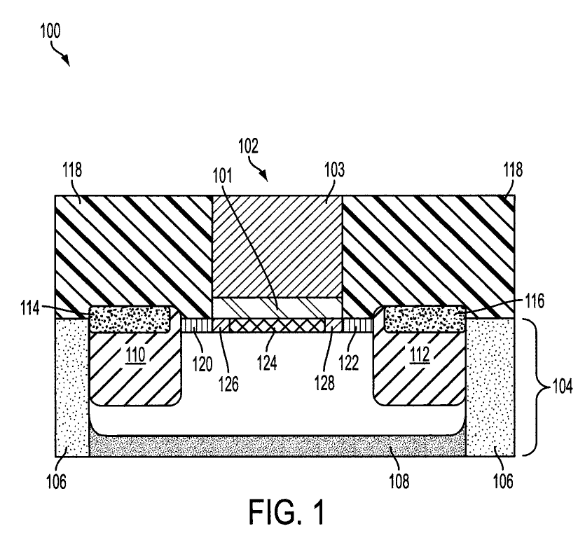

FIG. 1 illustrates a side cut-away view of an exemplary embodiment of a field effect transistor (FET) device 100. The device 100 includes a gate stack portion 102 disposed on channel region 124 of a substrate 104. The gate stack portion 102 may include, for example layer 101 disposed on the substrate 104, and a layer 103 disposed on the layer 101. The layer 101 may include a dielectric material, such as silicon dioxide or a high-k layer of material. The layer 103 may include a polysilicon material or a metallic gate material. The substrate may include for example a silicon trench isolation (STI) portion 106 and a buried oxide portion 108.

The device 100 includes a source region 110 and a drain region 112. The source and drain regions 110 and 112 may be formed from epitaxially grown silicon material including, for example SiC. The source and drain regions 110 and 112 may include silicide regions 114 and 116 that include a silicide material such as, for example NiPtSi. A spacer material 118, such as, for example, silicon nitride or silicon oxide may be formed over the device 100.

The device 100 includes a source extension portion 120 and a drain extension portion 122. The source extension portion 120 extends from the source region 110 to a channel region 124 and the drain extension portion 122 extends from the drain region 112 to the channel region 124. The channel region 124 includes transition regions 126 and 128. The device 100 may be a p-type FET (PFET) or n-type FET (NFET) depending on the dopants used to fabricate the device 100. For a NFET device, the device 100 would include source and drain extension portions 120 and 122 that are primarily n-type doped, the channel region 124 includes primarily p-type dopants, and the transition regions 126 and 128 include both p-type and n-type dopants. The transition regions 126 and 128 include a ratio of n-type and p-type dopants such that the transition regions exhibit p-type properties. The interface or junction between the transition regions 126 and 128 and the source extension portion 120 and the drain extension portion 122 are aligned with the distal regions (edges) of the gate stack 102. A PFET device is similar to the NFET device described above however, the source and drain extension portions 120 and 122 are primarily p-type doped, and the channel region 124 includes n-type dopants. The transition regions 126 and 128 include a ratio of n-type and p-type dopants such that the transition regions exhibit n-type properties.

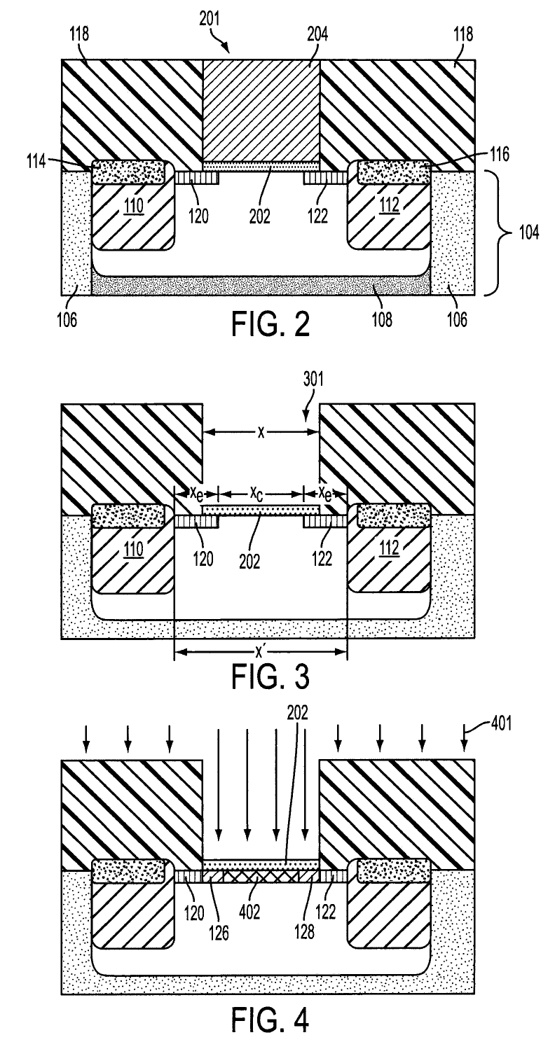

FIGS. 2-6 illustrate a side cut-away view of an exemplary method for fabricating the device 100 (of FIG. 1). Referring to FIG. 2, the illustrated embodiment includes a substrate 104 that includes a buried oxide portion 108 and a STI portion 106. A source region 110 and a drain region 112 include doped silicon material that may be formed from any suitable process such as, for example, epitaxially growing silicon that may be doped during the growth process, or during a subsequent doping process. A silicide material 114 and 116 may be formed on the source region 110 and the drain region 112 using a suitable silicidation process. A dummy gate stack 201 includes a interfacial layer 202 that may include, for example, an oxide or dielectric material disposed on the substrate 104 and a polysilicon material 204 disposed on the interfacial layer 202. A spacer material 118 that may include, for example, a nitride or oxide material is formed adjacent to the dummy gate stack 201 and over the source and drain regions 110 and 112. Doped source extension portion 120 and drain extension portion 122 extend from the source and drain regions 110 and 112 respectively to a region overlapped by the dummy gate 201.

FIG. 3 illustrates the resultant structure following the removal of the polysilicon material 204 (of FIG. 2) from the dummy gate stack 201. The removal of the polysilicon material 204 exposes the interfacial layer 202 and forms a cavity 301 defined by the spacer material 118 and the interfacial layer 202 having a width (x). The distance between the source and drain regions 110 and 112 has a length (x′). The source extension portion 120 and drain extension portion 122 each have lengths (xₑ) while the channel region between the source extension portion 120 and drain extension portion 122 has a length (x_{c}), such that x′=xₑ+xₑ+x_{c}, and x′>x.

FIG. 4 illustrates the resultant structure following the implantation of ions 401 and an annealing process such as, for example, a laser annealing process, that forms a doped channel region 402 and transition regions 126 and 128. The type of ions 401 used may be determined by the type of FET device desired. For example, for an NFET device, the source extension portion 120 and drain extension portion 122 are n-type doped. Thus, p-type ions are used to form the channel region 402 and the transition regions 126 and 128. The channel region 402 includes primarily p-type ions, while the transition regions 126 and 128 include both p-type and n-type. The ratio of p-type to n-type ions includes at least a slightly greater concentration of p-type to n-type such that the transition regions 126 and 128 exhibit p-type properties. In an exemplary method for forming a PFET device, the source extension portion 120 and drain extension portion 122 are p-type doped, and n-type ions are used to form the channel region 402 and the transition regions 126 and 128. The transition regions 126 and 128 include a greater concentration of n-type ions such that the transition regions 126 and 128 and the channel region 402 exhibit n-type properties.

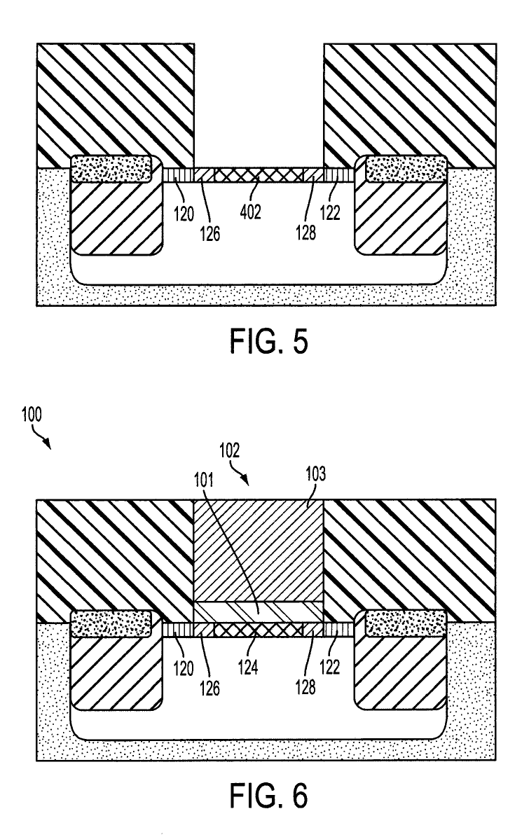

FIG. 5 illustrates the resultant structure following the removal of the exposed interfacial layer 202 (of FIG. 4). The interfacial layer 202 may be removed using a suitable etching process such as, for example, a chemical wet etching process.

FIG. 6 illustrates the formation of the gate stack portion 102 on the channel region 124. The gate stack portion 102 may include, for example layer 101 disposed on the substrate 104, and a layer 103 disposed on the layer 101. The layer 101 may include a dielectric material, such as silicon dioxide or a high-k layer of material. The layer 103 may include a polysilicon material or a metallic gate material.

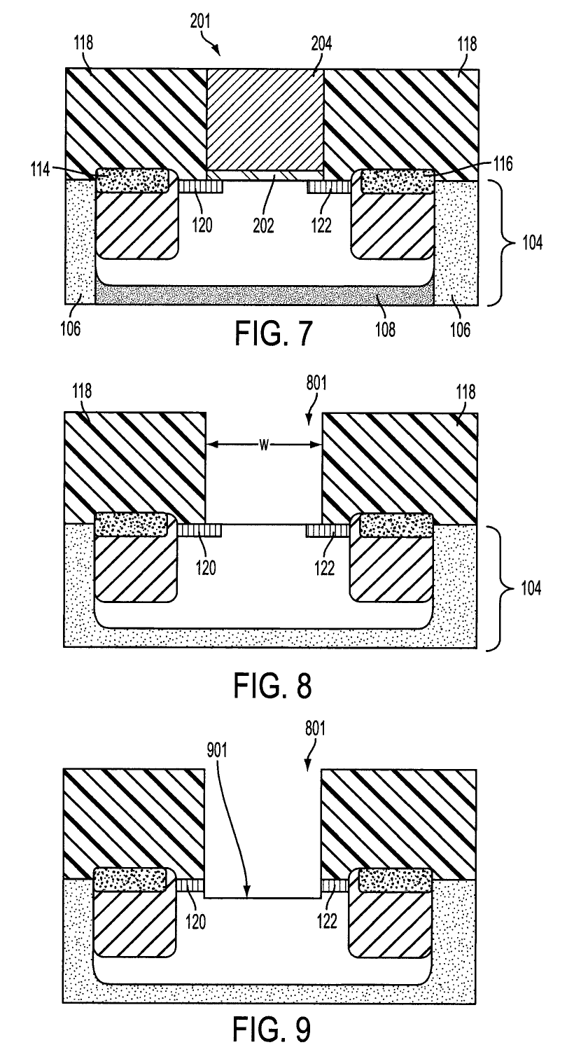

FIGS. 7-11 illustrate an alternate exemplary method for forming a FET device 200 (described below). Referring to FIG. 7, the elements of FIG. 7 are similar to the elements of FIG. 2 described above, and include a substrate 104 that includes a buried oxide portion 108 and a STI portion 106. A source region 110 and a drain region 112 include doped silicon material that may be formed from any suitable process such as, for example, epitaxially growing silicon that may be doped during the growth process, or during a subsequent doping process. A silicide material 114 and 116 may be formed on the source region 110 and the drain region 112 using a suitable silicidation process. A dummy gate stack 201 includes a interfacial layer 202 that may include, for example, an oxide or dielectric material disposed on the substrate 104 and a polysilicon material 204 disposed on the interfacial layer 202. A spacer material 118 that may include, for example, a nitride or oxide material is formed adjacent to the dummy gate stack 201 and over the source and drain regions 110 and 112. Doped source extension portion 120 and drain extension portion 122 extend from the source and drain regions 110 and 112 respectively to a region overlapped by the dummy gate 201.

FIG. 8 illustrates the resultant structure following the removal of the dummy gate stack 201 (of FIG. 7) using a suitable etching process such as, for example, a reactive ion etching process or a wet etching process. The removal of the dummy gate stack 201 results in the formation of a cavity 801 having a width (w) that is defined by the spacer material 118 and the substrate 104 that includes exposed portions of the source extension portion 120 and drain extension portion 122.

FIG. 9 illustrates the resultant structure following the removal of portions of the substrate 104 including the exposed portions of the source extension portion 120 and drain extension portion 122 that increases the depth of the cavity 801 and forms a trench (or cavity) 901 in the substrate 104.

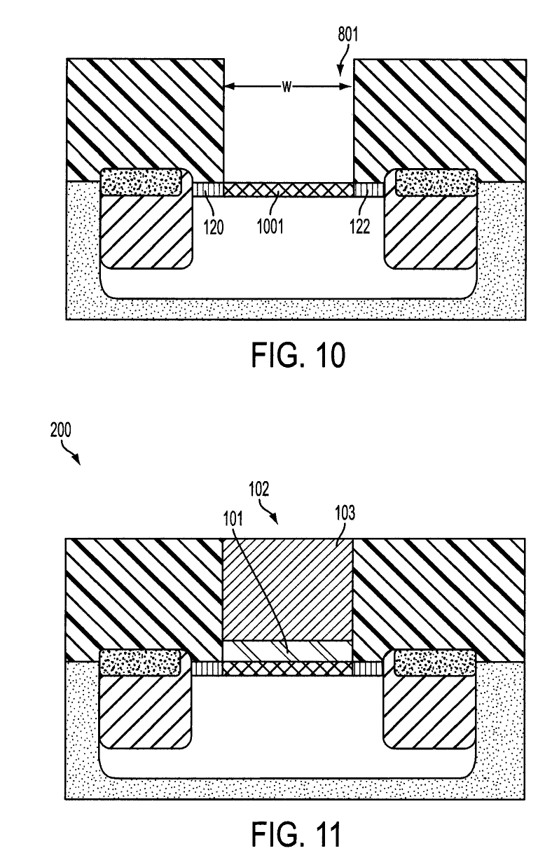

FIG. 10 illustrates the formation of a channel region 1001 that fills the trench 901. The channel region 1001 may be formed by, for example epitaxially grown silicon material such as silicon, SiGe or another semiconductor material. The channel region 1001 may be doped with ions (p-type or n-type) in-situ (i.e., during growth process) or following the growth using a suitable ion implantation method. The resultant structure includes the channel region 1001 having a width w and interfaces, or junctions between the channel region 1001 and the source extension portion 120 and drain extension portion 122 that are aligned with distal edges of the gate stack (described below).

FIG. 11 illustrates the formation of a gate stack portion 102 that is similar to the gate stack portion 102 described above in FIG. 1 and is formed on the exposed channel region 1001.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A field effect transistor device including:
a substrate including a source region, a drain region, and a channel region disposed between the source region and the drain region, wherein the source region is connected to the channel region with a source extension portion, and the drain region is connected to the channel region with a drain extension portion, wherein the channel region includes a source transition portion including n-type and p-type ions and a drain transition portion including n-type and p-type ions; and
a gate stack portion disposed on the channel region.

2. The device of claim 1, wherein the channel region includes a region disposed between the source transition portion and the drain transition portion that includes n-type ions.

3. The device of claim 1, wherein the channel region includes a region disposed between the source transition portion and the drain transition portion that includes p-type ions.

4. The device of claim 2, wherein the source extension portion and the drain extension portion are doped with p-type ions.

5. The device of claim 3, wherein the source extension portion and the drain extension portion are doped with n-type ions.

6. The device of claim 1, wherein the channel region includes an epitaxially grown silicon region disposed between the source transition portion and the drain transition portion.

7. The device of claim 1, wherein the channel region includes an epitaxially grown doped silicon region disposed between the source transition portion and the drain transition portion.

8. The device of claim 1, wherein the gate stack includes a dielectric material layer and a polysilicon material layer disposed on the dielectric material layer.

9. The device of claim 1, wherein the gate stack includes a dielectric material layer and a metallic material layer disposed on the dielectric material layer.

10. The device of claim 8, wherein the dielectric material layer includes a high-K material.

11. A field effect transistor device including:
a substrate including a source region, a drain region, and a cavity disposed between the source region and the drain region,
a channel region including a doped silicon material disposed in the cavity, wherein the source region is connected to the channel region with a source extension portion, and the drain region is connected to the channel region with a drain extension portion; and
a gate stack portion disposed on the channel region.

12. The device of claim 11, wherein the doped silicon material includes an epitaxially grown silicon material.

13. The device of claim 11, wherein the doped silicon material disposed in the cavity includes n-type ions.

14. The device of claim 11, wherein the doped silicon material disposed in the cavity includes p-type ions.

15. The device of claim 11, wherein the source extension portion and the drain extension portion are doped with p-type ions.

16. The device of claim 11, wherein the source extension portion and the drain extension portion are doped with n-type ions.

17. The device of claim 11, wherein the gate stack includes a dielectric material layer and a polysilicon material layer disposed on the dielectric material layer.

18. The device of claim 11, wherein the gate stack includes a dielectric material layer and a metallic material layer disposed on the dielectric material layer.

19. The device of claim 18, wherein the dielectric material layer includes a high-K material.

20. The device of claim 17, wherein the dielectric material layer includes a high-K material.
